(19) United States
(12) Patent Application Publication
(10) Pub. No.: US 2026/0031036 A1
(43) Pub. Date: Jan. 29, 2026

(54) DISPLAY DEVICE INCLUDING LIGHT SENSING PIXEL

(71) Applicant: Samsung Display Co., Ltd., Yongin-si (KR)

(72) Inventors: HYUNDAE LEE, Yongin-si (KR); JUNGWOO PARK, Yongin-si (KR); KANGBIN JO, Yongin-si (KR)

(21) Appl. No.: 19/096,295

(22) Filed: Mar. 31, 2025

(30) Foreign Application Priority Data
Jul. 26, 2024 (KR) 10-2024-0099519

(51) Int. Cl. G09G 3/3233; G06V 40/13; G09G 3/20

(52) U.S. Cl. CPC G09G 3/3233; G06V 40/1318; G09G 3/2007; G09G 2300/0819; G09G 2300/0842; G09G 2300/0861; G09G 2310/08; G09G 2320/0257; G09G 2320/0626; G09G 2354/00; G09G 2360/145

(57) ABSTRACT

A display device includes: a display panel including a light emitting pixel having a light emitting element and a light sensing pixel having an organic photodiode within a sensing region; and a panel driver configured to drive the display panel, the panel driver further configured to: drive the light emitting pixel to emit light with a first luminance in a first period; reset the organic photodiode of the light sensing pixel in a second period; drive the light emitting pixel to emit light with a second luminance such that the organic photodiode receives reflected light in a third period; and receive a sensing current corresponding to an intensity of the reflected light from the light sensing pixel in a fourth period, wherein the first luminance in the first period is higher than the second luminance in the third period.

### CROSS-REFERENCE TO RELATED APPLICATION

The present application claims priority to and the benefit of Korean Patent Application No. 10-2024-0099519, filed on Jul. 26, 2024, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

Electronic devices (e.g., a smart phone, a smart watch, etc.) may be utilized to perform bio-sensing operations, e.g., a fingerprint sensing operation, a photoplethysmography (PPG) sensing operation, etc. These electronic devices may perform the bio-sensing operations using a sensor that is separate from a display device. In this case, the size of a display region of the display device may be relatively reduced, and the size of a bezel may be relatively increased.

An in-cell light sensor technique may be utilized that employs an optical sensor or a light sensing pixel within the display region of the display device.

The above information disclosed in this Background section is only for enhancement of understanding of the background and therefore the information discussed in this Background section does not necessarily constitute prior art.

### SUMMARY

Aspects of some embodiments of the present disclosure relate to a display device, and for example, to a display device including a light sensing pixel having an organic photodiode.

Aspects of some embodiments include a display device capable of eliminating or reducing a sensing error caused by an image that is displayed before a sensing operation is performed.

Aspects of some embodiments include a method of operating a display device capable of removing or reducing a sensing error caused by an image that is displayed before a sensing operation is performed.

According to some embodiments, a display device includes a display panel including a light emitting pixel having a light emitting element and a light sensing pixel having an organic photodiode within a sensing region, and a panel driver configured to drive the display panel. According to some embodiments, the panel driver drives the light emitting pixel to emit light with a first luminance in a first period, resets the organic photodiode of the light sensing pixel in a second period, drives the light emitting pixel emit light with a second luminance such that the organic photodiode receives reflected light in a third period, and receives a sensing current corresponding to an intensity of the reflected light from the light sensing pixel in a fourth period. According to some embodiments, the first luminance in the first period is higher than the second luminance in the third period.

According to some embodiments, the second luminance may be lower than a maximum luminance of the light emitting pixel in a normal mode, and the first luminance may be higher than the maximum luminance of the light emitting pixel in the normal mode.

According to some embodiments, the panel driver may provide a first data voltage to the light emitting pixel such that the light emitting pixel emits light with the first luminance in the first period, and may provide a second data voltage different from the first data voltage to the light emitting pixel such that the light emitting pixel emits light with the second luminance in the third period.

According to some embodiments, the light emitting pixel may include a P-type driving transistor, and the first data voltage may be lower than the second data voltage.

According to some embodiments, the second data voltage may be higher than a data voltage corresponding to a maximum gray level in the normal mode, and the first data voltage may be lower than the data voltage corresponding to the maximum gray level in the normal mode.

According to some embodiments, in the first period, a leakage current may flow from the light emitting pixel to the light sensing pixel, and a voltage of an internal node connected to the organic photodiode may be changed based on the leakage current.

According to some embodiments, the panel driver may drive the light emitting pixel to emit light with the second luminance in the second period.

According to some embodiments, each of the first period and the second period may correspond to at least one frame period.

According to some embodiments, the first period may correspond to a first frame period, and the second period may correspond to a second frame period.

According to some embodiments, the first period may correspond to a first frame period, and the second period may correspond to second and third frame periods.

According to some embodiments, the first period and the second period may correspond to a same frame period.

According to some embodiments, the light emitting pixel may not emit light in the second period.

According to some embodiments, the sensing region may be a fingerprint sensing region that senses a fingerprint of a user.

According to some embodiments, the panel driver may include a data driver configured to provide a data voltage to the light emitting pixel through a data line, a scan driver configured to provide a write signal to the light emitting pixel and the light sensing pixel, and to further provide a compensation signal, an initialization signal and a bypass signal to the light emitting pixel, an emission driver configured to provide an emission signal to the light emitting pixel, and a readout circuit connected to the light sensing pixel through a readout line, and configured to provide a global reset signal to the light sensing pixel.

According to some embodiments, the light emitting pixel may include a first transistor configured to generate a driving current, a second transistor configured to transfer the data voltage in response to the write signal, a third transistor configured to diode-connect the first transistor in response to the compensation signal, a fourth transistor configured to transfer an initialization voltage to a gate of the first transistor in response to the initialization signal, a fifth transistor configured to connect a line which transfers a first power supply voltage and the first transistor in response to the emission signal, a sixth transistor configured to connect the first transistor and the light emitting element in response to the emission signal, a seventh transistor configured to transfer an anode initialization voltage to the light emitting element in response to the bypass signal, a storage capacitor connected between the line which transfers the first power supply voltage and the gate of the first transistor, and the light emitting element configured to emit light based on the driving current.

According to some embodiments, the light sensing pixel may include an eighth transistor configured to generate the sensing current based on a voltage of an internal node connected to the organic photodiode, a ninth transistor configured to transfer a reset voltage to the internal node in response to the global reset signal, a tenth transistor configured to connect the eighth transistor and the readout line in response to the write signal, and the organic photodiode.

According to some embodiments, the global reset signal may have an on-level in the first period and the second period.

According to some embodiments, in a method of operating a display device including a light emitting pixel and a light sensing pixel within a sensing region, the light emitting pixel is driven to emit light with a first luminance in a first period, an organic photodiode of the light sensing pixel is reset in a second period, the light emitting pixel is driven to emit light with a second luminance such that the organic photodiode receives reflected light in a third period, and a sensing current corresponding to an intensity of the reflected light is received from the light sensing pixel in a fourth period. The first luminance in the first period is higher than the second luminance in the third period.

According to some embodiments, the second luminance may be lower than a maximum luminance of the light emitting pixel in a normal mode, and the first luminance may be higher than the maximum luminance of the light emitting pixel in the normal mode.

According to some embodiments, a first data voltage provided to the light emitting pixel to emit light with the first luminance may be lower than a second data voltage provided to the light emitting pixel to emit light with the second luminance.

According to some embodiments, an electronic device includes a processor configured to provide image data, and a display device configured to display an image based on the image data. According to some embodiments, the display device includes a display panel including a light emitting pixel having a light emitting element and a light sensing pixel having an organic photodiode within a sensing region, and a panel driver configured to drive the display panel. According to some embodiments, the panel driver drives the light emitting pixel to emit light with a first luminance in a first period, resets the organic photodiode of the light sensing pixel in a second period, drives the light emitting pixel to emit light with a second luminance such that the organic photodiode receives reflected light in a third period, and receives a sensing current corresponding to an intensity of the reflected light from the light sensing pixel in a fourth period. According to some embodiments, the first luminance in the first period is higher than the second luminance in the third period.

As described above, in a display device and a method of operating the display device according to some embodiments, a light emitting pixel may be driven to emit light with a first luminance in a first period of a sensing period, an organic photodiode of a light sensing pixel may be reset in a second period of the sensing period, the light emitting pixel may be driven to emit light with a second luminance such that the organic photodiode receives reflected light in a third period of the sensing period, and a sensing current corresponding to an intensity of the reflected light may be received from the light sensing pixel in a fourth period of the sensing period. Further, the first luminance in the first period may be higher than the second luminance in the third period. Accordingly, a sensing error caused by an image displayed before a sensing operation is performed may be eliminated or reduced.

### BRIEF DESCRIPTION OF THE DRAWINGS

Illustrative, non-limiting embodiments will be more clearly understood from the following detailed description in conjunction with the accompanying drawings.

FIG. 1 is a block diagram illustrating a display device according to some embodiments.

FIG. 2 is a circuit diagram illustrating an example of a light emitting pixel and a light sensing pixel included in a display device according to some embodiments.

FIG. 3A and FIG. 3B are drawings for describing an example of a sensing operation performed in a display device according to some embodiments.

FIG. 4A is a drawing illustrating an example of an image displayed in a sensing region before a sensing operation is performed, and FIG. 4B is a timing diagram for describing an example of voltages of internal nodes of light sensing pixels having a deviation caused by the image of FIG. 4A in a conventional display device.

FIG. 5 is a timing diagram for describing an example of a sensing operation performed in a display device according to some embodiments.

FIG. 6 is a drawing illustrating an example of a digital sensing signal generated in a display device according to some embodiments as an image.

FIG. 7 is a flowchart illustrating a method of operating a display device according to some embodiments.

FIG. 8 is a timing diagram for describing an example of a sensing operation performed in a display device according to some embodiments.

FIG. 9 is a drawing illustrating an example of digital sensing signals according to a first data voltage.

FIG. 10 is a flowchart illustrating a method of operating a display device according to some embodiments.

FIG. 11 is a timing diagram for describing an example of a sensing operation performed in a display device according to some embodiments.

FIG. 12 is a flowchart illustrating a method of operating a display device according to some embodiments.

FIG. 13 is a timing diagram for describing an example of a sensing operation performed in a display device according to some embodiments.

FIG. 14 is a flowchart illustrating a method of operating a display device according to some embodiments.

FIG. 15 is a timing diagram for describing an example of a sensing operation performed in a display device according to some embodiments.

FIG. 16 is a block diagram illustrating an electronic device including a display device according to some embodiments.

### DETAILED DESCRIPTION

Hereinafter, aspects of some embodiments of the present inventive concept will be explained in more detail with reference to the accompanying drawings.

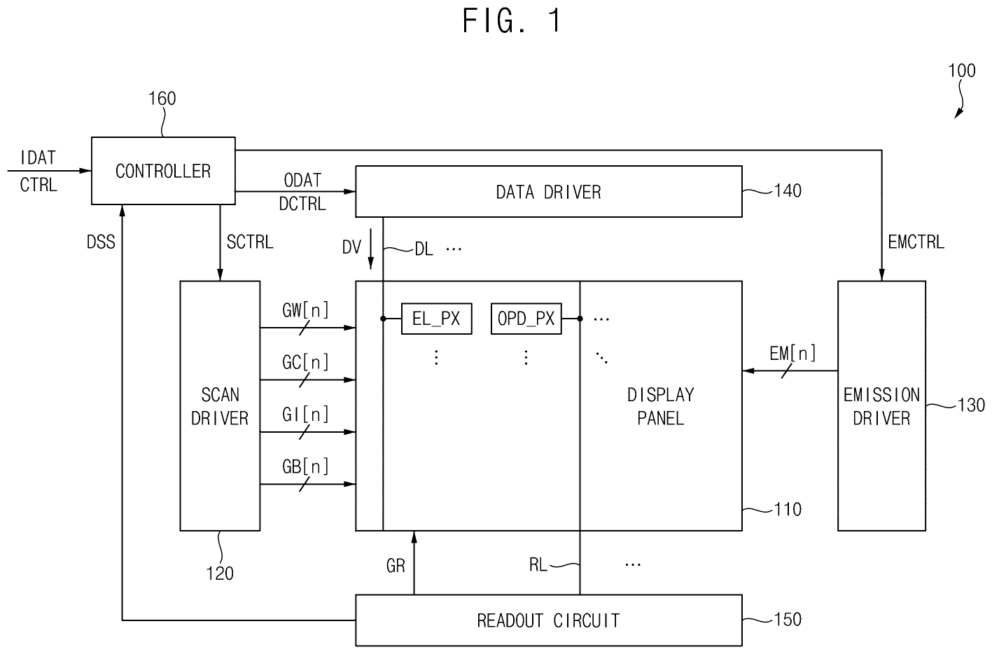

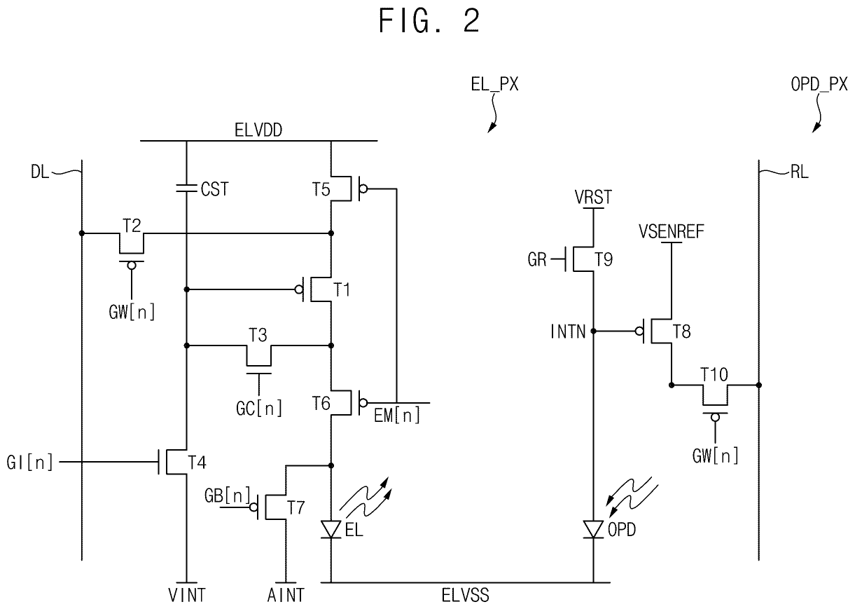

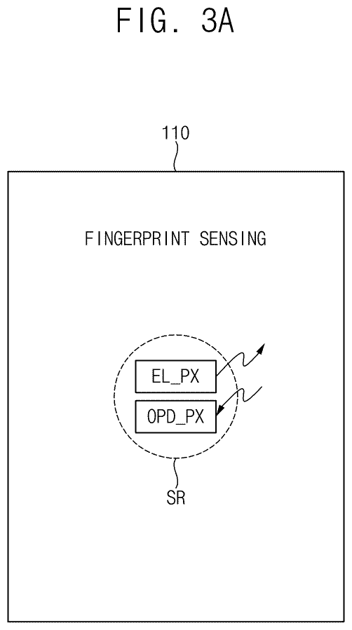

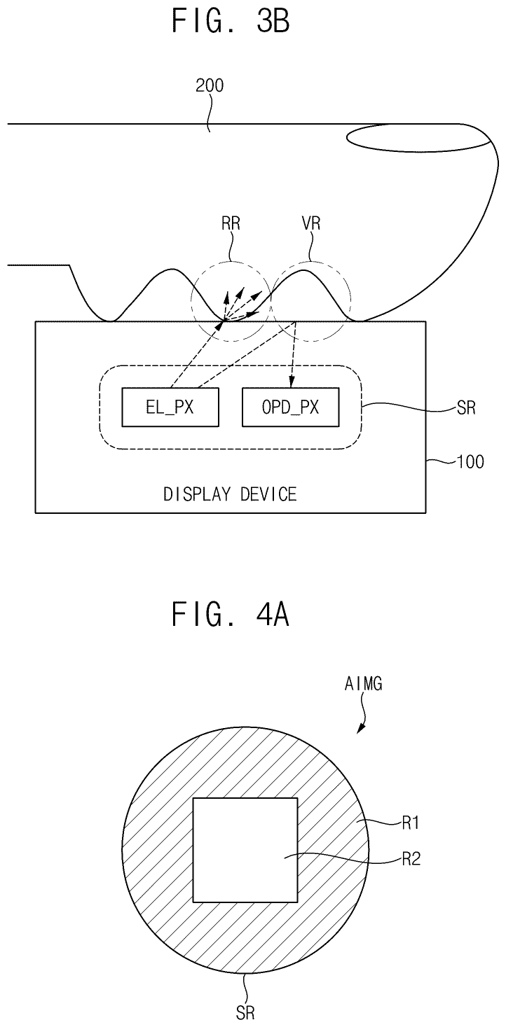

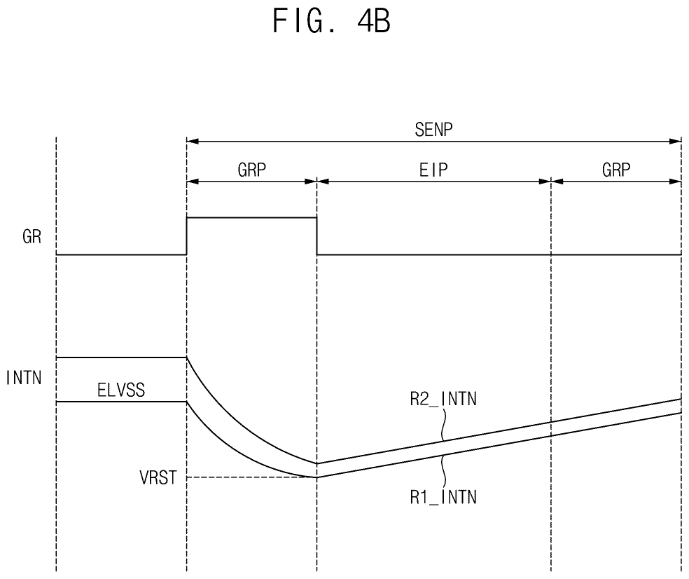

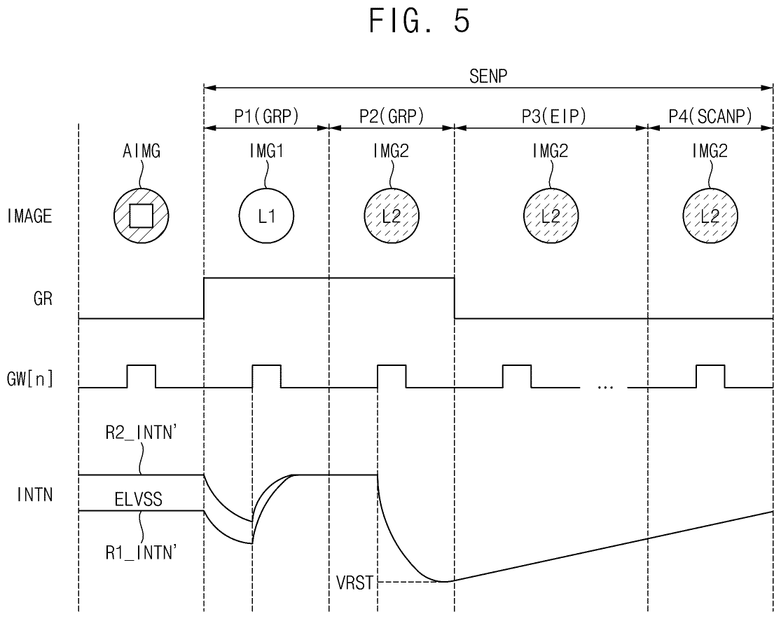

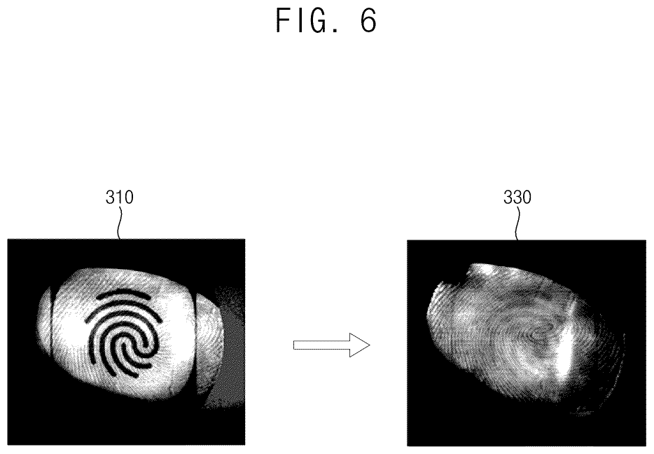

FIG. 1 is a block diagram illustrating a display device according to some embodiments, FIG. 2 is a circuit diagram illustrating an example of a light emitting pixel and a light sensing pixel included in a display device according to some embodiments, FIG. 3A and FIG. 3B are drawings for describing an example of a sensing operation performed in a display device according to some embodiments, FIG. 4A is a drawing illustrating an example of an image displayed in a sensing region before a sensing operation is performed, FIG. 4B is a timing diagram for describing an example of voltages of internal nodes of light sensing pixels having a deviation caused by the image of FIG. 4A in a conventional display device, FIG. 5 is a timing diagram for describing an example of a sensing operation performed in a display device according to some embodiments, and FIG. 6 is a drawing illustrating an example of a digital sensing signal generated in a display device according to some embodiments as an image.

Referring to FIG. 1, a display device 100 according to some embodiments may include a display panel 110 that includes a light emitting pixel EL_PX and a light sensing pixel OPD_PX, and a panel driver that drives the display panel 110. According to some embodiments, the panel driver may include a scan driver 120 that provides scan signals GW[n], GC[n], GI[n] and GB[n] to the light emitting pixel EL_PX and/or the light sensing pixel OPD_PX, an emission driver 130 that provides an emission signal EM[n] to the light emitting pixel EL_PX, a data driver 140 that provides a data voltage DV to the light emitting pixel EL_PX, a readout circuit 150 connected to the light sensing pixel OPD_PX through a readout line RL, and a controller 160 that controls an operation of the display device 100.

The display panel 110 may include light emitting pixels EL_PX and light sensing pixels OPD_PX. According to some embodiments, the light emitting pixels EL_PX and the light sensing pixels OPD_PX may be arranged in the entire region of the display panel 110. According to some embodiments, the light emitting pixels EL_PX may be arranged in the entire region of the display panel 110, and the light sensing pixels OPD_PX may be arranged in a partial region (e.g., a sensing region SR illustrated in FIG. 3A) of the display panel 110. According to some embodiments, the light emitting pixels EL_PX may include red light emitting pixels, green light emitting pixels, and blue light emitting pixels. Further, according to some embodiments, in the display panel 110, four light emitting pixels EL_PX (e.g., one red light emitting pixel, two green light emitting pixels and one blue light emitting pixel) may be arranged in a diamond shape, and one light sensing pixel OPD_PX may be arranged among the four light emitting pixels EL_PX arranged in the diamond shape, but are not limited thereto. In this case, the number of the light sensing pixels OPD_PX may correspond to, but is not limited to, the number of green light emitting pixels or half of the number of green light emitting pixels. According to some embodiments, each light emitting pixel EL_PX may include a light emitting element, and may emit light by using the light emitting element. Further, each light sensing pixel OPD_PX may include an organic photodiode, and may sense light by using the organic photodiode.

For example, as illustrated in FIG. 2, the light emitting pixel EL_PX may include a first transistor T1, a second transistor T2, a third transistor T3, a fourth transistor T4, a fifth transistor T5, a sixth transistor T6, a seventh transistor T7, a storage capacitor CST and a light emitting element EL. Although FIG. 2 illustrates various components in a light emitting pixel EL_PX and a light sensing pixel OPD_PX according to some embodiments, embodiments according to the present disclosure are not limited thereto, and according to various embodiments the light emitting pixel and the light sensing pixel may include additional components or fewer components without departing from the spirit and scope of embodiments according to the present disclosure.

The first transistor T1 may generate a driving current based on a voltage stored in the storage capacitor CST. The first transistor T1 may be referred to as a driving transistor for generating the driving current. According to some embodiments, the first transistor T1 may include a gate connected to the storage capacitor CST, a first terminal connected to the fifth transistor T5, and a second terminal connected to the sixth transistor T6.

The second transistor T2 may transfer the data voltage DV of a data line DL to the first terminal of the first transistor T1 in response to a write signal GW[n]. According to some embodiments, the second transistor T2 may include a gate which receives the write signal GW[n], a first terminal connected to the data line DL, and a second terminal connected to the first terminal of the first transistor T1.

The third transistor T3 may diode-connect the first transistor T1 in response to a compensation signal GC[n]. According to some embodiments, the third transistor T3 may include a gate which receives the compensation signal GC[n], a first terminal connected to the second terminal of the first transistor T1, and a second terminal connected to the gate of the first transistor T1.

The fourth transistor T4 may transfer an initialization voltage VINT to the gate of the first transistor T1 in response to an initialization signal GI[n]. According to some embodiments, the fourth transistor T4 may include a gate which receives the initialization signal GI[n], a first terminal connected to the gate of the first transistor T1, and a second terminal connected to a line which transfers the initialization voltage VINT.

The fifth transistor T5 may connect a line which transfers a first power supply voltage ELVDD (e.g., a high power supply voltage) and the first transistor T1 in response to the emission signal EM[n]. According to some embodiments, the fifth transistor T5 may include a gate which receives the emission signal EM[n], a first terminal connected to the line which transfers the first power supply voltage ELVDD, and a second terminal connected to the first terminal of the first transistor T1.

The sixth transistor T6 may connect the first transistor T1 and the light emitting element EL in response to the emission signal EM[n]. According to some embodiments, the sixth transistor T6 may include a gate which receives the emission signal EM[n], a first terminal connected to the second terminal of the first transistor T1, and a second terminal connected to an anode of the light emitting element EL.

The seventh transistor T7 may transfer an anode initialization voltage AINT to the light emitting element EL in response to a bypass signal GB[n]. According to some embodiments, the seventh transistor T7 may include a gate which receives the bypass signal GB[n], a first terminal connected to the anode of the light emitting element EL, and a second terminal connected to a line which transfers the anode initialization voltage AINT. According to some embodiments, the initialization voltage VINT and the anode initialization voltage AINT may be different voltages. According to some embodiments, the initialization voltage VINT and the anode initialization voltage AINT may be the same voltage.

The storage capacitor CST may be connected between the line which transfers the first power supply voltage ELVDD and the gate of the first transistor T1. According to some embodiments, the storage capacitor CST may include a first electrode connected to the line which transfers the first power supply voltage ELVDD, and a second electrode connected to the gate of the first transistor T1.

The light emitting element EL may emit light based on the driving current generated by the first transistor T1. According to some embodiments, the light emitting element EL may be, but is not limited to, an organic light emitting diode (“OLED”). According to some embodiments, the light emitting element EL may be a nano light emitting diode (“NED”), a quantum dot (“QD”) light emitting diode, a micro light emitting diode, an inorganic light emitting diode, or any other suitable light emitting element. According to some embodiments, the light emitting element EL may include the anode connected to the sixth transistor T6, and a cathode connected to a line which transfers a second power supply voltage ELVSS (e.g., a low power supply voltage).

According to some embodiments, the first through seventh transistors T1 through T7 may be P-type metal-oxide-semiconductor (“PMOS”) transistors. According to some embodiments, the first through seventh transistors T1 through T7 may be N-type metal-oxide-semiconductor (“NMOS”) transistors. According to some embodiments, one or more of the first through seventh transistors T1 through T7 may be PMOS transistors, and one or more others of the first through seventh transistors T1 through T7 may be NMOS transistors. For example, as illustrated in FIG. 2, the first, second, fifth, sixth and seventh transistors T1, T2, T5, T6 and T7 may be PMOS transistors, and the third and fourth transistors T3 and T4 may be NMOS transistors, but are not limited thereto. Although FIG. 2 illustrates an example in which the light emitting pixel EL_PX has a 7T1C structure including seven transistors T1 through T8 and one capacitor CST, a structure of the light emitting pixel EL_PX of the display device 100 according to some embodiments is not limited to the example of FIG. 2.

Further, for example, as illustrated in FIG. 2, the light sensing pixel OPD_PX may include an eighth transistor T8, a ninth transistor T9, a tenth transistor T10 and an organic photodiode OPD.

The eighth transistor T8 may generate a sensing current based on a voltage of an internal node INTN connected to the organic photodiode OPD (e.g., an anode of the organic photodiode OPD). According to some embodiments, the eighth transistor T8 may include a gate connected to the internal node INTN, a first terminal which receives a sensing reference voltage VSENREF, and a second terminal. According to some embodiments, the sensing reference voltage VSENREF may have a voltage level that is the same (or substantially the same) as a voltage level of the second power supply voltage ELVSS, but is not limited thereto.

The ninth transistor T9 may transfer a reset voltage VRST to the internal node INTN in response to a global reset signal GR. Thus, the ninth transistor T9 may reset the internal node INTN or the organic photodiode OPD connected to the internal node INTN to the reset voltage VRST. Here, resetting the organic photodiode OPD may mean that the voltage of the internal node INTN connected to the organic photodiode OPD (or an anode voltage of the organic photodiode OPD) changes to the reset voltage VRST. According to some embodiments, the ninth transistor T9 may include a gate which receives the global reset signal GR, a first terminal which receives the reset voltage VRST, and a second terminal connected to the internal node INTN.

The tenth transistor T10 may connect the eighth transistor T8 and the readout line RL in response to the write signal GW[n]. Thus, the tenth transistor T10 may transfer the sensing current generated by the eighth transistor T8 to the readout line RL in response to the write signal GW[n]. According to some embodiments, the tenth transistor T10 may include a gate which receives the write signal GW[n], a first terminal connected to the second terminal of the eighth transistor T8, and a second terminal connected to the readout line RL.

The organic photodiode OPD may be used to measure an intensity of light. For example, after the voltage of the internal node INTN connected to the organic photodiode OPD is reset to the reset voltage VRST, the voltage of the internal node INTN may be increased by different amounts depending on the intensity of light applied to the organic photodiode OPD. For example, when light of relatively high intensity is applied to the organic photodiode OPD, a current (e.g., a reverse leakage current) of the organic photodiode OPD applied from the line which transfers the second power supply voltage ELVSS to the internal node INTN may have a relatively large amount, and the voltage of the internal node INTN may be increased by a relatively large amount due to the current of the organic photodiode OPD. In contrast, when light of relatively low intensity is applied to the organic photodiode OPD, the current of the organic photodiode OPD applied from the line which transfers the second power supply voltage ELVSS to the internal node INTN may have a relatively small amount, and the voltage of the internal node INTN may be increased by a relatively small amount due to the current of the organic photodiode OPD. Further, the sensing current of the eighth transistor T8 may be determined according to the voltage of the internal node INTN, and the readout circuit 150 may generate a digital sensing signal DSS corresponding to the sensing current. Thus, a value of the digital sensing signal DSS generated by the readout circuit 150 may be determined according to the intensity of light applied to the organic photodiode OPD. According to some embodiments, the organic photodiode OPD may include, but is not limited to, an anode connected to the internal node INTN, and a cathode connected to the line which transfers the second power supply voltage ELVSS.

According to some embodiments, the eighth through tenth transistors T8 through T10 may be PMOS transistors. According to some embodiments, the eighth through tenth transistors T8 through T10 may be NMOS transistors. According to some embodiments, one or more of the eighth through tenth transistors T8 through T10 may be PMOS transistors, and one or more others of the eighth through tenth transistors T8 through T10 may be NMOS transistors. For example, as illustrated in FIG. 2, the eighth and tenth transistors T8 and T10 may be PMOS transistors, and the ninth transistor T9 may be an NMOS transistor, but are not limited thereto. Although FIG. 2 illustrates an example in which the light sensing pixel OPD_PX has a 3T1D structure including three transistors T8 through T10 and one organic photodiode OPD, a structure of the light sensing pixel OPD_PX of the display device 100 according to some embodiments is not limited to the example of FIG. 2.

The scan driver 120 may generate the scan signals GW[n], GC[n], GI[n] and GB[n] based on a scan control signal SCTRL received from the controller 160, and may sequentially provide the scan signals GW[n], GC[n], GI[n] and GB[n] to the display panel 110 on a row-by-row basis. The scan control signal SCTRL may include, but is not limited to, a scan start signal and a scan clock signal. According to some embodiments, the scan driver 120 may generate, as the scan signals, the write signal GW[n], the compensation signal GC[n], the initialization signal GI[n] and the bypass signal GB[n] illustrated in FIG. 2, may provide the write signal GW[n], the compensation signal GC[n], the initialization signal GI[n] and the bypass signal GB[n] to the light emitting pixel EL_PX, and may provide the write signal GW[n] to the light sensing pixel OPD_PX. Further, according to some embodiments, the scan driver 120 may be integrated or formed in the display panel 110. According to some embodiments, the scan driver 120 may be implemented as one or more integrated circuits.

The emission driver 130 may generate the emission signals EM[n] based on an emission control signal EMCTRL received from the controller 160, and may sequentially provide the emission signals EM[n] to the light emitting pixels EL_PX of the display panel 110 on a row-by-row basis. The emission control signal EMCTRL can include, but is not limited to, an emission start signal and an emission clock signal. According to some embodiments, the emission driver 130 may be integrated or formed in the display panel 110. According to some embodiments, the emission driver 130 may be implemented as one or more integrated circuits.

The data driver 140 may generate the data voltages DV based on a data control signal DCTRL and output image data ODAT received from the controller 160, and may provide the data voltages DV to the light emitting pixels EL_PX through the data lines DL. The data control signal DCTRL may include, but is not limited to, an output data enable signal, a horizontal start signal, and a load signal. According to some embodiments, the data driver 140 and the controller 160 may be implemented as a single integrated circuit, and the single integrated circuit may be referred to as a timing controller embedded data driver (“TED”) integrated circuit. According to some embodiments, the data driver 140 and the controller 160 may be implemented as separate integrated circuits.

The readout circuit 150 may be connected to the light sensing pixels OPD_PX through the readout lines RL. The readout circuit 150 may receive sensing currents of the light sensing pixels OPD_PX through the readout lines RL, may generate the digital sensing signal DSS based on the sensing currents, and may provide the digital sensing signal DSS to the controller 160. Further, the readout circuit 150 may simultaneously (or substantially simultaneously) or concurrently apply the global reset signal GR to all the light sensing pixels OPD_PX of the display panel 110. According to some embodiments, the readout circuit 150 may be implemented as an integrated circuit, and the integrated circuit may be referred to as a read-out integrated circuit (“ROIC”). According to some embodiments, the readout circuit 150 may be included in the data driver 140.

The controller 160 (e.g., a timing controller) may receive input image data IDAT and a control signal CTRL from an external host processor (e.g., a graphics processing unit (“GPU”), an application processor (“AP”), or a graphics card). According to some embodiments, the input image data IDAT may be RGB image data including red image data, green image data and blue image data. According to some embodiments, the control signal CTRL may include, but is not limited to, a vertical synchronization signal, a horizontal synchronization signal, an input data enable signal, a master clock signal, etc. The controller 160 may generate the output image data ODAT, the data control signal DCTRL, the scan control signal SCTRL and the emission control signal EMCTRL based on the input image data IDAT and the control signal CTRL. The controller 160 may control an operation of the data driver 140 by providing the output image data ODAT and the data control signal DCTRL to the data driver 140, may control an operation of the scan driver 120 by providing the scan control signal SCTRL to the scan driver 120, and may control an operation of the emission driver 130 by providing the emission control signal EMCTRL to the emission driver 130.

The panel driver of the display device 100 according to some embodiments may perform a bio-sensing operation, such as a fingerprint sensing operation, a photoplethysmography sensing operation, etc., by driving the light sensing pixels OPD_PX and/or the light emitting pixels EL_PX in the sensing region SR illustrated in FIG. 3A. According to some embodiments, the panel driver may perform a sensing operation that senses a fingerprint of a finger placed on the sensing region SR. For example, as illustrated in FIGS. 3A and 3B, the panel driver may drive the light emitting pixels EL_PX within the sensing region SR of the display panel 110 such that the light emitting pixels EL_PX within the sensing region emit light. Here, the sensing region SR may be a fingerprint sensing region on which a finger 200 of a user is placed to sense the fingerprint of the user. Light emitted from the light emitting pixel EL_PX arranged corresponding to a ridge region RR of the fingerprint of the finger 200 may be transmitted into the ridge region RR, but light emitted from the light emitting pixel EL_PX arranged corresponding to a valley region VR of the fingerprint of the finger 200 may be reflected from the valley region VR (or from a surface of the display panel 110 corresponding to the valley region VR). Each light sensing pixel OPD_PX within the sensing region SR may generate the sensing current by sensing light that is generated from the light emitting pixel EL_PX immediately adjacent to the light sensing pixel OPD_PX and is reflected from the fingerprint of the finger 200. The readout circuit 150 may generate the digital sensing signal DSS representing the fingerprint of the finger 200 based on the sensing currents of the light sensing pixels OPD_PX within the sensing region SR.

However, in a conventional display device, a sensing error may occur due to an image displayed in the sensing region SR immediately before a sensing operation is performed. For example, if an image AIMG including a low-luminance image and a high-luminance image respectively for a first region R1 and a second region R2 of the sensing region SR as illustrated in FIG. 4A is displayed immediately before the sensing operation is performed, as illustrated in FIG. 4B, before a sensing period SENP in which the sensing operation is performed, a voltage R1_INTN of an internal node INTN of a light sensing pixel OPD_PX in the first region R1 may have a relatively low voltage level, and a voltage R2_INTN of an internal node INTN of a light sensing pixel OPD_PX in the second region R2 may have a relatively high voltage level. The difference between the internal node voltages R1_INTN and R2_INTN of the light sensing pixels OPD_PX of the first and second regions R1 and R2 may be caused by leakage currents (e.g., lateral leakage currents) from the light emitting pixels EL_PX adjacent to the light sensing pixels OPD_PX of the first and second regions R1 and R2. For example, the light emitting pixel EL_PX in the first region R1 displaying the low-luminance image (or a black image) may not (or hardly) provide the lateral leakage current to the internal node INTN of the light sensing pixel OPD_PX in the first region R1, and the internal node voltage R1_INTN of the light sensing pixel OPD_PX in the first region R1 may become the second power supply voltage ELVSS by the current through the organic photodiode OPD from the line which transfers the second power supply voltage ELVSS. However, the light emitting pixel EL_PX in the second region R2 displaying the high-luminance image (or a white image) may generate a relatively large driving current, and the lateral leakage current proportional to the driving current may flow to the internal node INTN of the light sensing pixel OPD_PX in the second region R2. For example, the light emitting element EL of the light emitting pixel EL_PX and the organic photodiode OPD of the light sensing pixel OPD_PX may share a common layer (e.g., a hole injection layer (“HIL”) and/or a hole transfer layer (“HTL”)), and the lateral leakage current may flow from the light emitting pixel EL_PX to the internal node INTN of the light sensing pixel OPD_PX through the common layer. Due to the lateral leakage current, the internal node voltage R2_INTN of the light sensing pixel OPD_PX in the second region R2 may be higher than the second power supply voltage ELVSS. In this case, even if the organic photodiodes OPD of the light sensing pixels OPD_PX in the first and second regions R1 and R2 are reset based on the reset voltage VSRT in a reset period GRP of the sensing period SENP, the internal node voltage R1_INTN of the light sensing pixel OPD_PX in the first region R1 may change to the reset voltage VSRT, but the internal node voltage R2_INTN of the light sensing pixel OPD_PX in the second region R2 may be higher than the reset voltage VSRT even at the end of the reset period GRP. Accordingly, even if light having the same intensity is applied to the organic photodiodes OPD of the light sensing pixels OPD_PX in the first and second regions R1 and R2 during an exposure and integration period EIP of the sensing period SENP, the readout circuit 150 may receive sensing currents having different amounts from the light sensing pixels OPD_PX in the first and second regions R1 and R2 in a scan period SCANP of the sensing period SENP, and may generate a digital sensing signal DSS having different values with respect to the first and second regions R1 and R2 based on the sensing currents having different amounts. That is, in the conventional display device, the image AIMG displayed immediately before the sensing period SENP in which the sensing operation is performed may affect the digital sensing signal DSS as an afterimage, and may cause a sensing error of the sensing operation.

To eliminate or relatively reduce the sensing error caused by the image AIMG displayed immediately before the sensing operation, in the display device 100 according to some embodiments, as illustrated in FIG. 5, the reset period GRP of the sensing period SENP may be divided into a first period P1 and a second period P2, and the light emitting pixels EL_PX of the sensing region SR may display a first image IMG1 having a first luminance L1 (e.g., high luminance) in the first period P1. For example, in the display device 100 according to some embodiments, the sensing period SENP in which the sensing operation (e.g., a fingerprint sensing operation) is performed may include the first period P1 in which the panel driver drives the light emitting pixels EL_PX of the sensing region SR such that the light emitting pixels EL_PX of the sensing region SR emit light with the first luminance L1, the second period P2 in which the panel driver resets the organic photodiodes OPD of the light sensing pixels OPD_PX of the sensing region SR, and a third period P3 in which the panel driver drives the light emitting pixels EL_PX of the sensing region SR such that the light emitting pixels EL_PX of the sensing region SR emit light with a second luminance L2 lower than the first luminance L1 and the organic photodiodes OPD of the light sensing pixels OPD_PX of the sensing region SR receive reflected light that is reflected from the finger of the user, and a fourth period P4 in which the panel driver receives sensing currents corresponding to the intensity of the reflected light from the light sensing pixels OPD_PX of the sensing region SR and generates the digital sensing signal DSS based on the sensing currents. Here, the first and second periods P1 and P2 may correspond to the reset period GRP in which the global reset signal GR has an on-level, the third period P3 may correspond to the exposure and integration period EIP in which light exposure and integration are performed, and the fourth period P4 may correspond to the scan period SCANP in which a scan operation is performed on the light sensing pixels OPD_PX.

As illustrated in FIG. 5, when the image AIMG illustrated in FIG. 4A is displayed immediately before the sensing period SENP in which the sensing operation is performed, the voltage R1_INTN′ of the internal node INTN of the light sensing pixel OPD_PX in the first region R1 may have the relatively low voltage level, and the voltage R2_INTN′ of the internal node INTN of the light sensing pixel OPD_PX in the second region R2 may have the relatively high voltage level. However, in the first period P1, because the light emitting pixels EL_PX of the first and second regions R1 and R2 display the first image IMG1 having the first luminance L1 higher than the second luminance L2 of a second image IMG2 for the sensing operation, the light emitting pixels EL_PX of the first and second regions R1 and R2 may generate large driving currents in response to the write signal GW[n] having the on-level, and large leakage currents (e.g., large lateral leakage currents) corresponding to the large driving currents may flow from the light emitting pixels EL_PX adjacent to the light sensing pixels OPD_PX to the light sensing pixels OPD_PX through the common layer (e.g., the HIL and/or the HTL) of the light emitting elements EL and the organic photodiodes OPD. By these lateral leakage currents, the internal node voltages R1_INTN′ and R2_INTN′ of the light sensing pixels OPD_PX of the first and second regions R1 and R2 may be changed (e.g., increased) to substantially the same voltage level.

Meanwhile, in the first period P1, the ninth transistor T9 of each light sensing pixel OPD_PX may be turned on in response to the global reset signal GR having the on-level, and a reset current may flow through the ninth transistor T9 from the internal node INTN to a line which transfers the reset voltage VRST lower than the second power supply voltage ELVSS. However, in the first period P1, because each light emitting pixel EL_PX of the sensing region SR emits light with the first luminance L1 higher than the second luminance L2 for the sensing operation, a sum of the lateral leakage current flowing from the light emitting pixel EL_PX adjacent to the light sensing pixel OPD_PX to the internal node INTN and the current flowing from the line which transfers the second power supply voltage ELVSS to the internal node INTN through the organic photodiode OPD receiving the reflected light having high intensity may be greater than the reset current through the ninth transistor T9, and thus the internal node voltages R1_INTN′ and R2_INTN′ of the respective light sensing pixels OPD_PX of the sensing region SR may be increased to substantially the same voltage level.

In the second period P2, the third period P3 and/or the fourth period P4 after the first period P1, the panel driver may drive the light emitting pixels EL_PX of the sensing region SR such that the light emitting pixels EL_PX of the sensing region SR may display the second image IMG2 having the second luminance L2.

In the second period P2, each light emitting pixel EL_PX of the sensing region SR may emit light with the second luminance L2 lower than the first luminance L1 in response to the write signal GW[n] having the on-level, and the lateral leakage current flowing from the light emitting pixel EL_PX to the light sensing pixel OPD_PX may be relatively reduced. Thus, by the reset current through the ninth transistor T9 that is turned on in response to the global reset signal GR having the on-level, the internal node voltage R1_INTN′ and R2_INTN′ of each light sensing pixel OPD_PX of the sensing region SR may become the reset voltage VRST.

In the third period P3, the global reset signal GR may be changed to an off-level, the organic photodiode OPD of the light sensing pixel OPD_PX may receive the reflected light that is reflected from the finger of the user, and the internal node voltage R1_INTN′ and R2_INTN′ may be gradually increased by a current (e.g., a reverse leakage current) flowing from the line which transfers the second power supply voltage ELVSS through the organic photodiode OPD to the internal node INTN. Meanwhile, the current flowing through the organic photodiode OPD may have different amounts depending on the intensity of the reflected light applied to the organic photodiode OPD, and thus the amount of increase (or slope) of the internal node voltages R1_INTN′ and R2_INTN′ may be determined depending on the intensity of the reflected light applied to the organic photodiode OPD.

In the fourth period P4, the write signals GW[n] having the on-level may be sequentially applied to the light sensing pixels OPD_PX of the sensing region SR on a row-by-row basis, and the light sensing pixels OPD_PX of the sensing region SR may provide the sensing currents corresponding to the internal node voltages R1_INTN′ and R2_INTN′ to the readout lines RL in response to the write signals GW[n] having the on-level. The readout circuit 150 may receive the sensing currents through the readout lines RL. Further, the readout circuit 150 may generate the digital sensing signal DSS representing the intensity of reflected light applied to the organic photodiodes OPD of the light sensing pixels OPD_PX of the sensing region SR based on the sensing currents.

The first luminance L1 of the first image IMG1 displayed in the first period P1 may be higher than the second luminance L2 of the second image IMG2 displayed in the third period P3 (or the second, third and fourth periods P2, P3 and P4) for the sensing operation or for generating the reflected light that is reflected from the finger of the user. According to some embodiments, the second luminance L2 may be lower than the maximum luminance of the light emitting pixel EL_PX in a normal mode in which the sensing operation is not performed, but the first luminance L1 may be higher than the maximum luminance of the light emitting pixel EL_PX in the normal mode. Here, the maximum luminance in the normal mode may mean the luminance of the light emitting pixel EL_PX when the data voltage DV corresponding to the maximum gray level (e.g., a 255-gray level) is provided to the light emitting pixel EL_PX.

Further, the panel driver may provide a first data voltage to the light emitting pixel EL_PX such that the light emitting pixel EL_PX emits light with the first luminance L1 in the first period P1, and may provide a second data voltage different from the first data voltage to the light emitting pixel EL_PX such that the light emitting pixel EL_PX emits light with the second luminance L2 in the third period P3 (or the second, third, and fourth periods P2, P3 and P4). According to some embodiments, in a case where the light emitting pixel EL_PX includes a P-type driving transistor as illustrated in FIG. 2, or in a case where the first transistor T1 is a PMOS transistor, the first data voltage provided to the light emitting pixel EL_PX in the first period P1 may be lower than the second data voltage provided to the light emitting pixel EL_PX in the third period P3. According to some embodiments, the second data voltage may be higher than the data voltage DV corresponding to the maximum gray level (e.g., a 255-gray level) in the normal mode, and the first data voltage may be lower than the data voltage DV corresponding to the maximum gray level in the normal mode.

Accordingly, as illustrated in FIG. 5, even if the image AIMG having different luminances with respect to the first and second regions R1 and R2 is displayed immediately before the sensing period SENP, the light emitting pixels EL_PX of the sensing region SR may emit light with the first luminance L1 higher than the second luminance L2 in the first period P1, the internal node voltages R1_INTN′ and R2_INTN′ of the light sensing pixels OPD_PX of the first and second regions R1 and R2 may be changed to the same (or substantially the same) voltage level, and the light sensing pixels OPD_PX of the first and second regions R1 and R2 may generate the same (or substantially the same) sensing current in response to the reflected light having the same intensity. Thus, in the display device 100 according to some embodiments, the sensing error caused by the image AIMG displayed in the sensing region SR immediately before the sensing operation is performed may be eliminated or relatively reduced. For example, as illustrated in FIG. 6, when a fingerprint image is displayed immediately before the sensing operation is performed in a conventional display device, an image 310 corresponding to a digital sensing signal DSS (i.e., an image expressing values indicated by the digital sensing signal DSS) generated in the conventional display device may include the fingerprint image as an afterimage. However, in the display device 100 according to some embodiments, even if the fingerprint image is displayed immediately before the sensing period SENP, an image 330 corresponding to the digital sensing signal DSS may have almost no afterimage of the fingerprint image.

As described above, in the display device 100 according to some embodiments, the light emitting pixel EL_PX may be driven to emit light with the first luminance L1 in the first period P1 of the sensing period SENP, the organic photodiode OPD of the light sensing pixel OPD_PX may be reset in the second period P2 of the sensing period SENP, the light emitting pixel EL_PX may be driven to emit light with the second luminance L2 such that the organic photodiode OPD may receive the reflected light in the third period P3 of the sensing period SENP, and the sensing current corresponding to the intensity of the reflected light may be received from the light sensing pixel OPD_PX in the fourth period P4 of the sensing period SENP. Further, the first luminance L1 in the first period P1 may be higher than the second luminance L2 in the third period P3 (or the second, third and fourth periods P2, P3 and P4). Accordingly, in the display device 100 according to some embodiments, the sensing error caused by the image AIMG displayed before the sensing operation is performed may be eliminated or relatively reduced.

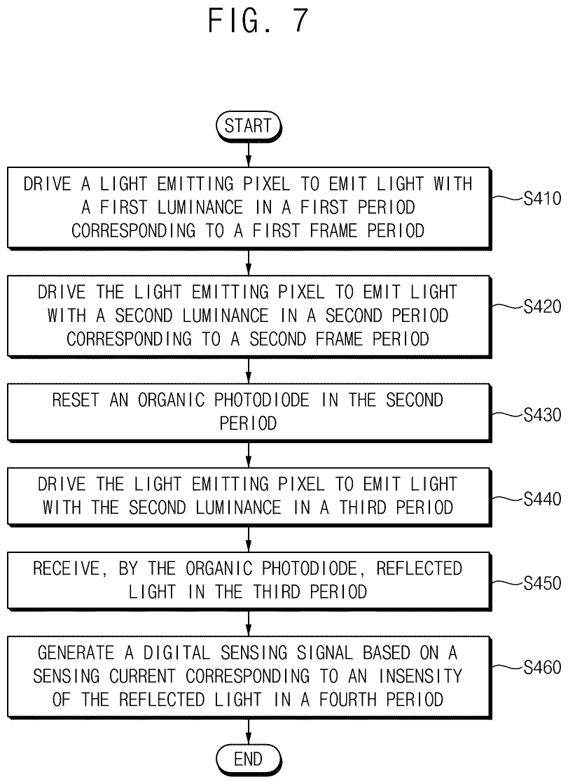

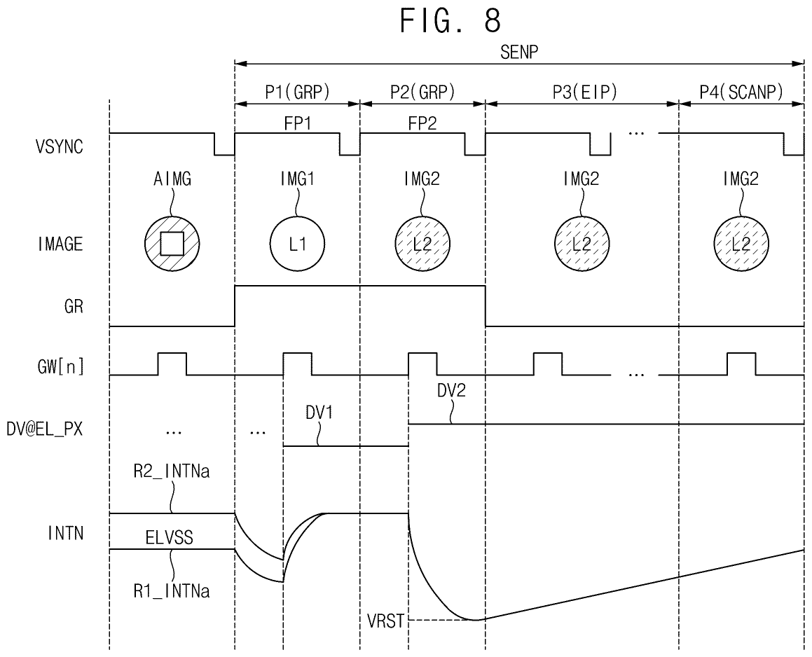

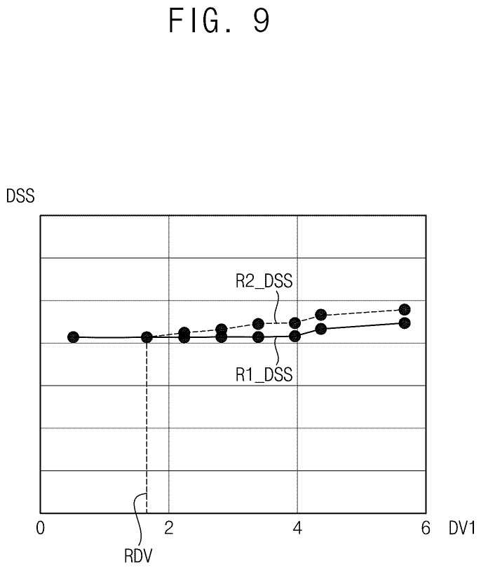

FIG. 7 is a flowchart illustrating aspects of a method of operating a display device according to some embodiments. Although FIG. 7 illustrates various operations in a method of operating a display device, embodiments according to the present disclosure are not limited thereto, and according to some embodiments, the method may include additional operations or fewer operations, or the order of operations may vary, unless otherwise stated or implied, without departing from the spirit and scope of embodiments according to the present disclosure. FIG. 8 is a timing diagram for describing an example of a sensing operation performed in a display device according to some embodiments, and FIG. 9 is a drawing illustrating an example of digital sensing signals according to a first data voltage.

Referring to FIGS. 1, 7 and 8, in a method of operating a display device 100 including a light emitting pixel EL_PX and a light sensing pixel OPD_PX within a sensing region, a panel driver of the display device 100 may drive the light emitting pixel EL_PX to display a first image IMG1 having a first luminance L1 in a first period P1 corresponding to a first frame period FP1 (S410). In FIG. 8, VSYNC may be a vertical synchronization signal for distinguishing frame periods FP1 and FP2. A data driver 140 of the panel driver may provide a first data voltage DV1 to the light emitting pixel EL_PX such that the light emitting pixel EL_PX may emit light with the first luminance L1. The first luminance L1 in the first period P1 may be higher than a second luminance L2 in second, third and fourth periods P2, P3 and P4. According to some embodiments, the second luminance L2 may be lower than the maximum luminance in a normal mode, and the first luminance L1 may be higher than the maximum luminance in the normal mode. When the light emitting pixel EL_PX emits light with the first luminance L1, a lateral leakage current may flow from the light emitting pixel EL_PX to the light sensing pixel OPD_PX, and a voltage R1_INTNa or R2_INTNa of an internal node INTN of the light sensing pixel OPD_PX may be changed (e.g., increased) by the lateral leakage current.

In a second period P2 corresponding to a second frame period FP2, the panel driver may drive the light emitting pixel EL_PX to display a second image IMG2 having a second luminance L2 (S420), and an organic photodiode of the light sensing pixel OPD_PX may be reset based on a reset voltage VRST (S430). In order for the light emitting pixel EL_PX to emit light with the second luminance L2, the data driver 140 may provide a second data voltage DV2 different from the first data voltage DV1 to the light emitting pixel EL_PX. According to some embodiments, as illustrated in FIG. 8, the first data voltage DV1 may be lower than the second data voltage DV2. In FIG. 8, DV@EL_PX may mean the data voltage DV provided to the light emitting pixel EL_PX. According to some embodiments, the second data voltage DV2 may be higher than the data voltage DV corresponding to the maximum gray level (e.g., a 255-gray level) in the normal mode, and the first data voltage DV1 may be lower than the data voltage DV corresponding to the maximum gray level in the normal mode. When the light emitting pixel EL_PX emits light with the second luminance L2, the lateral leakage current flowing from the light emitting pixel EL_PX to the light sensing pixel OPD_PX may be relatively reduced. Further, the light sensing pixel OPD_PX may reset the organic photodiode or the internal node INTN connected to the organic photodiode to the reset voltage VRST in response to the global reset signal GR having an on-level. According to some embodiments, as illustrated in FIG. 8, the global reset signal GR may have the on-level (e.g., a high level) in the first and second periods P1 and P2.

In a third period P3, the panel driver may drive the light emitting pixel EL_PX to display the second image IMG2 having the second luminance L2 (S440), and a readout circuit 150 of the panel driver may change the global reset signal GR to an off-level. The organic photodiode of the light sensing pixel OPD_PX may receive reflected light that is reflected from a finger placed on the sensing region (S450), and the voltage R1_INTNa and R2_INTNa of the internal node INTN may be gradually increased by a current flowing through the organic photodiode. The amount of increase (or slope) of the voltage R1_INTNa and R2_INTNa of the internal node INTN may be determined according to the intensity of the reflected light.

In a fourth period P4, the panel driver may provide a write signal GW[n] to the light sensing pixel OPD_PX (and the light emitting pixel EL_PX), the light sensing pixel OPD_PX may transfer a sensing current corresponding to the intensity of the reflected light to a readout line RL in response to the write signal GW[n], and the readout circuit 150 may generate a digital sensing signal DSS based on the sensing current received through the readout line RL (S460).

Even if an image AIMG having different luminances with respect to first and second regions of the sensing region is displayed before the sensing period SENP, and the internal node voltages R1_INTNa and R2_INTNa of the light sensing pixels OPD_PX of the first and second regions have different voltage levels, in the first period P1, the first data voltage DV1 lower than the second data voltage DV2 may be provided to the light emitting pixels EL_PX of the first and second regions, and the lateral leakage currents may flow from the light emitting pixels EL_PX of the first and second regions to the light sensing pixels OPD_PX of the first and second regions, respectively. The internal node voltages R1_INTNa and R2_INTNa of the light sensing pixels OPD_PX of the first and second regions may be increased to the same (or substantially the same) voltage level by the lateral leakage currents.

FIG. 9 illustrates an example of digital sensing signals R1_DSS and R2_DSS for the first and second regions according to the first data voltage DV1 provided to the light emitting pixels EL_PX in the first period P1. As illustrated in FIG. 9, in a case where the first data voltage DV1 is lower than a reference data voltage RDV, even if the image AIMG having the different luminances for the first and second regions is displayed before the sensing period SENP, the digital sensing signals R1_DSS and R2_DSS for the first and second regions may have the same (or substantially the same) value. According to some embodiments, the reference data voltage RDV may be lower than the data voltage DV corresponding to the maximum gray level in the normal mode, but is not limited thereto.

As described above, in the method of operating the display device 100 according to some embodiments, in the first period P1 corresponding to the first frame period FP1, the first data voltage DV1 lower than the second data voltage DV2 may be provided to the light emitting pixel EL_PX, and the light emitting pixel EL_PX may emit light with the first luminance L1 higher than the second luminance L2. Accordingly, a sensing error caused by the image AIMG displayed before the sensing operation is performed may be eliminated or relatively reduced.

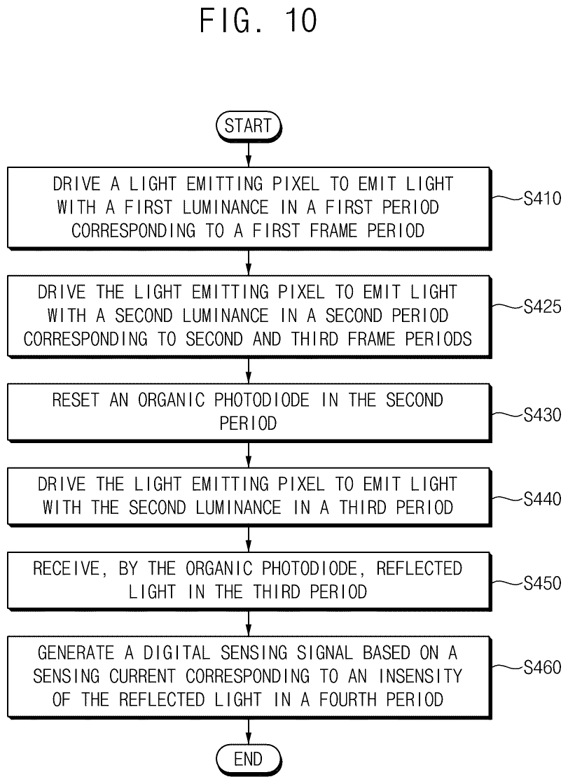

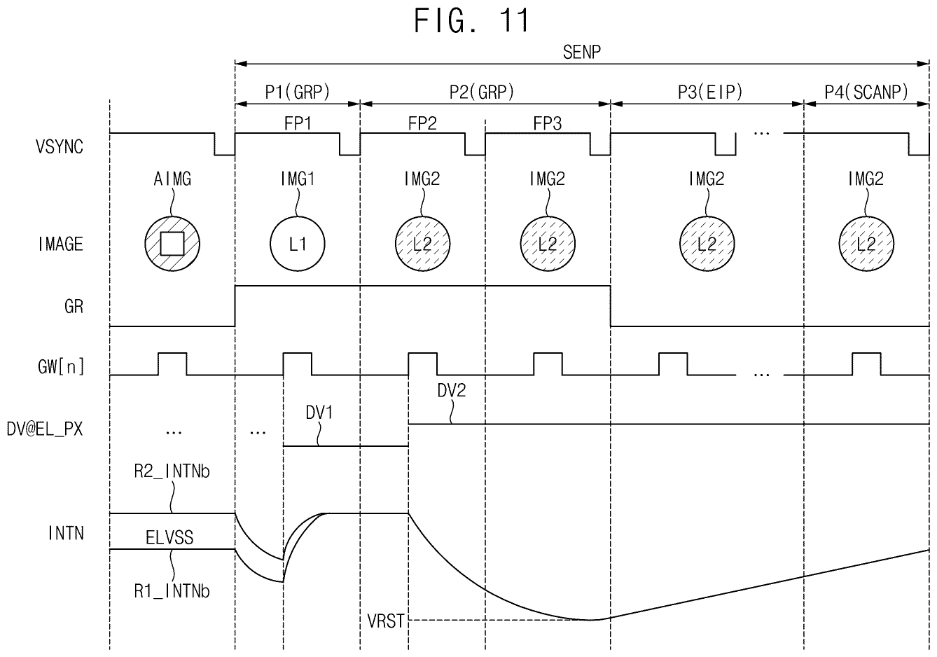

FIG. 10 is a flowchart illustrating aspects of a method of operating a display device according to some embodiments. Although FIG. 10 illustrates various operations in a method of operating a display device, embodiments according to the present disclosure are not limited thereto, and according to some embodiments, the method may include additional operations or fewer operations, or the order of operations may vary, unless otherwise stated or implied, without departing from the spirit and scope of embodiments according to the present disclosure. FIG. 11 is a timing diagram for describing an example of a sensing operation performed in a display device according to some embodiments.

A method of FIG. 10 and a timing diagram of FIG. 11 may be the same (or substantially the same) as a method of FIG. 7 and a timing diagram of FIG. 8, except that the second period P2 corresponds to two frame periods, or second and third frame periods FP2 and FP3.

Referring to FIGS. 1, 10 and 11, in the second and third frame periods FP2 and FP3, the panel driver may drive the light emitting pixel EL_PX to display the second image IMG2 having the second luminance L2 (S425), and the organic photodiode of the light sensing pixel OPD_PX may be reset based on the reset voltage VRST (S430). In the method of operating the display device 100 illustrated in FIGS. 10 and 11, compared with the method of operating the display device 100 illustrated in FIGS. 7 and 8, a time length of the second period P2 in which the organic photodiode is reset may be increased, and thus the internal node voltage R1_INTNb and R2_INTNb of the light sensing pixel OPD_PX may be reset to the reset voltage VRST more stably.

Although FIGS. 8 and 11 illustrate examples in which the first period P1 corresponds to one frame period FP1, the first period P1 in the method of operating the display device 100 according to some embodiments is not limited to the examples of FIGS. 8 and 11. For example, the first period P1 may correspond to two or more frame periods. Further, although FIG. 8 illustrates an example in which the second period P2 corresponds to one frame period FP2, and FIG. 11 illustrates an example in which the second period P2 corresponds to two frame periods FP2 and FP3, the second period P2 in the method of operating the display device 100 according to some embodiments is not limited to the examples of FIG. 8 and FIG. 11. For example, the second period P2 may correspond to three or more frame periods.

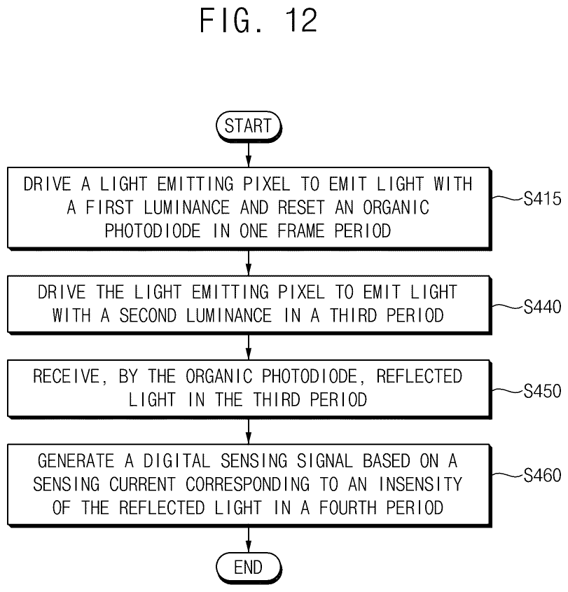

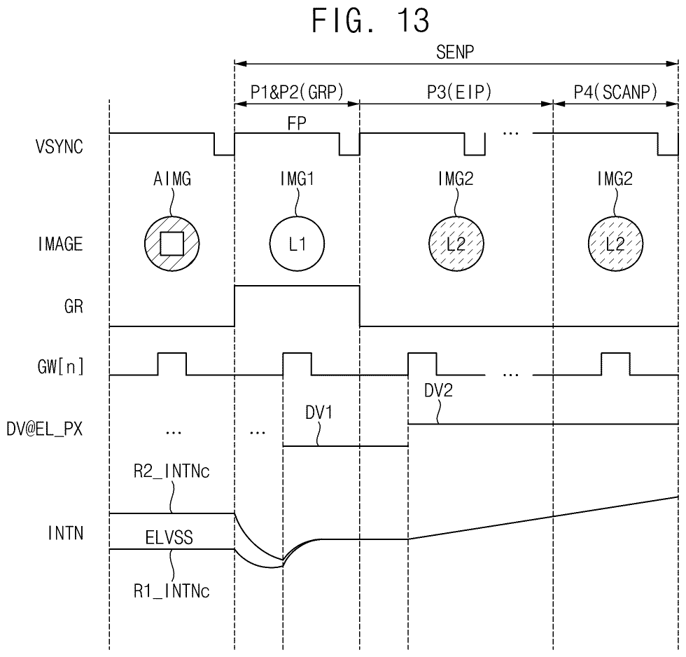

FIG. 12 is a flowchart illustrating a method of operating a display device according to some embodiments. Although FIG. 12 illustrates various operations in a method of operating a display device, embodiments according to the present disclosure are not limited thereto, and according to some embodiments, the method may include additional operations or fewer operations, or the order of operations may vary, unless otherwise stated or implied, without departing from the spirit and scope of embodiments according to the present disclosure. FIG. 13 is a timing diagram for describing an example of a sensing operation performed in a display device according to some embodiments.

A method of FIG. 12 and a timing diagram of FIG. 13 may be the same (or substantially the same) as a method of FIG. 7 and a timing diagram of FIG. 8, except that the first period P1 and the second period P2 may overlap each other and that the first and second periods P1 and P2 correspond to one frame period FP.

Referring to FIGS. 1, 12 and 13, in one frame period FP, the panel driver may drive the light emitting pixel EL_PX to emit light with the first luminance L1, and the organic photodiode of the light sensing pixel OPD_PX may be reset (e.g., to a voltage higher than the reset voltage VRST) (S445). In the frame period FP, the global reset signal GR may have the on-level, and a reset current may flow from the internal node INTN of the light sensing pixel OPD_PX to the line which transfers the reset voltage VRST in response to the global reset signal GR having the on-level. However, in the frame period FP, because the lateral leakage current flows from the light sensing pixel OPD_PX to the light sensing pixel OPD_PX, the internal node voltage R1_INTNc and R2_INTNc of the light sensing pixel OPD_PX may be changed to a voltage level higher than the reset voltage VRST. In the method of operating the display device 100 illustrated in FIGS. 12 and 13, because the first and second periods P1 and P2 correspond to the same frame period FP, a time length of the sensing period SENP may be shortened, and the sensing operation may be performed more quickly.

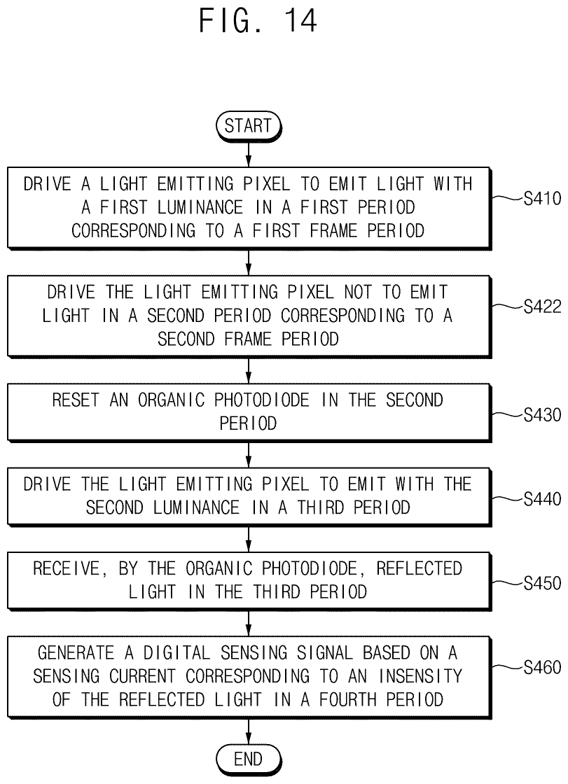

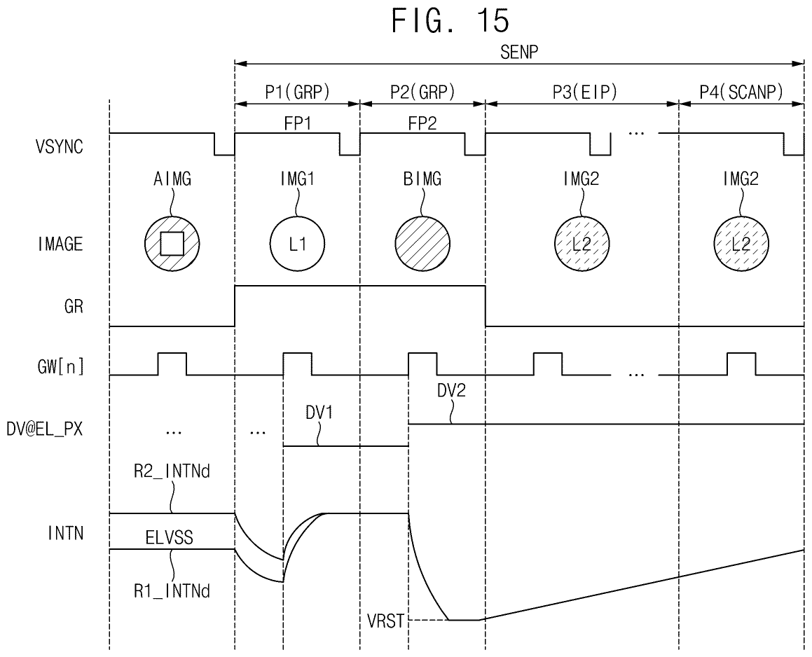

FIG. 14 is a flowchart illustrating a method of operating a display device according to some embodiments. Although FIG. 14 illustrates various operations in a method of operating a display device, embodiments according to the present disclosure are not limited thereto, and according to some embodiments, the method may include additional operations or fewer operations, or the order of operations may vary, unless otherwise stated or implied, without departing from the spirit and scope of embodiments according to the present disclosure. FIG. 15 is a timing diagram for describing an example of a sensing operation performed in a display device according to some embodiments.

A method of FIG. 14 and a timing diagram of FIG. 15 may be the same (or substantially the same) as a method of FIG. 7 and a timing diagram of FIG. 8, except that the light emitting pixel EL_PX displays a black image BIMG in the second period P2, or that the light emitting pixel EL_PX does not emit light in the second period P2.

Referring to FIGS. 1, 14 and 15, in the second period P2, the panel driver may drive the light emitting pixel EL_PX to display the black image BIMG (e.g., having a luminance of 0), or such that the light emitting pixel EL_PX does not emit light (S422), and the organic photodiode of the light sensing pixel OPD_PX may be reset based on the reset voltage VRST (S430). Because the light emitting pixel EL_PX does not emit light, the lateral leakage current may not flow from the light emitting pixel EL_PX to the light sensing pixel OPD_PX, and the organic photodiode of the light sensing pixel OPD_PX may not receive the reflected light. Accordingly, in the method of operating the display device 100 illustrated in FIGS. 14 and 15, the internal node voltage R1_INTNd and R2_INTNd of the light sensing pixel OPD_PX may be reset to the reset voltage VRST more quickly than in the method of operating the display device 100 illustrated in FIGS. 7 and 8.

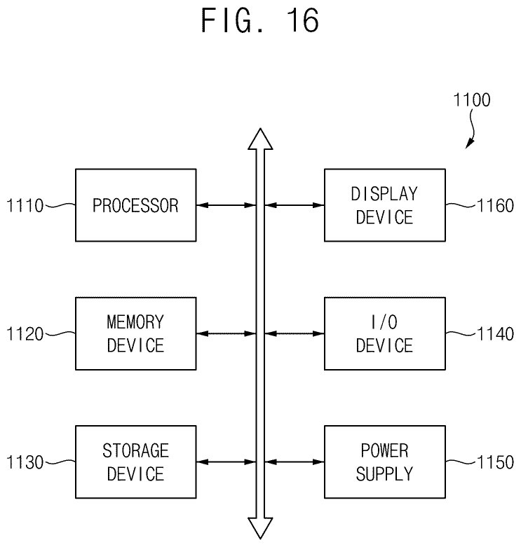

FIG. 16 is a block diagram illustrating an electronic device including a display device according to some embodiments.

Referring to FIG. 16, an electronic device 1100 may include a processor 1110, a memory device 1120, a storage device 1130, an input/output (I/O) device 1140, a power supply 1150 and a display device 1160. The electronic device 1100 may further include a plurality of ports for communicating with a video card, a sound card, a memory card, a universal serial bus (“USB”) device, other electric devices, etc.

The processor 1110 may perform various computing functions or tasks. The processor 1110 may be an application processor (“AP”), a micro-processor, a central processing unit (“CPU”), etc. The processor 1110 may be coupled to other components via an address bus, a control bus, a data bus, etc. Further, according to some embodiments, the processor 1110 may be further coupled to an extended bus such as a peripheral component interconnection (“PCI”) bus.

The memory device 1120 may store data for operations of the electronic device 1100. For example, the memory device 1120 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, etc., and/or at least one volatile memory device such as a dynamic random access memory (“DRAM”) device, a static random access memory (“SRAM”) device, a mobile dynamic random access memory (“mobile DRAM”) device, etc.

The storage device 1130 may be a solid state drive (“SSD”) device, a hard disk drive (“HDD”) device, a compact disc-read only memory (“CD-ROM”) device, etc. The I/O device 1140 may be an input device such as a keyboard, a keypad, a mouse, a touch screen, etc., and an output device such as a printer, a speaker, etc. The power supply 1150 may supply power for operations of the electronic device 1100. The display device 1160 may be coupled to other components through the buses or other communication links.

In the display device 1160, a light emitting pixel may be driven to emit light with a first luminance in a first period of a sensing period, an organic photodiode of a light sensing pixel may be reset in a second period of the sensing period, the light emitting pixel may be driven to emit light with a second luminance such that the organic photodiode receives reflected light in a third period of the sensing period, and a sensing current corresponding to the intensity of the reflected light may be received from the light sensing pixel in a fourth period of the sensing period. Further, the first luminance in the first period may be higher than the second luminance in the third period. Accordingly, a sensing error caused by an image displayed before a sensing operation is performed may be eliminated or relatively reduced.

The inventive concepts may be applied any electronic device 1100 including the display device 1160. For example, the inventive concepts may be applied to a mobile phone, a smart phone, a virtual reality (“VR”) device, a television (“TV”) (e.g., a digital TV, a three-dimensional (“3D”) TV, etc.), a wearable electronic device, a personal computer (“PC”) (e.g. a laptop computer, a tablet computer, etc.), a home appliance, a personal digital assistant (“PDA”), a portable multimedia player (“PMP”), a digital camera, a music player, a portable game console, a navigation device, etc.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, and their equivalents.

What is claimed is:

1. A display device comprising:
a display panel including a light emitting pixel having a light emitting element and a light sensing pixel having an organic photodiode within a sensing region; and
a panel driver configured to drive the display panel, the panel driver further configured to:
drive the light emitting pixel to emit light with a first luminance in a first period;
reset the organic photodiode of the light sensing pixel in a second period;
drive the light emitting pixel to emit light with a second luminance such that the organic photodiode receives reflected light in a third period; and
receive a sensing current corresponding to an intensity of the reflected light from the light sensing pixel in a fourth period,
wherein the first luminance in the first period is higher than the second luminance in the third period.

2. The display device of claim 1, wherein the second luminance is lower than a maximum luminance of the light emitting pixel in a normal mode, and
wherein the first luminance is higher than the maximum luminance of the light emitting pixel in the normal mode.

3. The display device of claim 1, wherein the panel driver is configured to provide a first data voltage to the light emitting pixel such that the light emitting pixel is configured to emit light with the first luminance in the first period, and is configured to provide a second data voltage different from the first data voltage to the light emitting pixel such that the light emitting pixel is configured to emit light with the second luminance in the third period.

4. The display device of claim 3, wherein the light emitting pixel includes a P-type driving transistor, and
wherein the first data voltage is lower than the second data voltage.

5. The display device of claim 4, wherein the second data voltage is higher than a data voltage corresponding to a maximum gray level in a normal mode, and
wherein the first data voltage is lower than the data voltage corresponding to the maximum gray level in the normal mode.

6. The display device of claim 1, wherein, in the first period, a leakage current flows from the light emitting pixel to the light sensing pixel, and a voltage of an internal node connected to the organic photodiode is changed based on the leakage current.

7. The display device of claim 1, wherein the panel driver is configured to drive the light emitting pixel to emit light with the second luminance in the second period.

8. The display device of claim 1, wherein each of the first period and the second period corresponds to at least one frame period.

9. The display device of claim 8, wherein the first period corresponds to a first frame period, and the second period corresponds to a second frame period.

10. The display device of claim 8, wherein the first period corresponds to a first frame period, and the second period corresponds to second and third frame periods.

11. The display device of claim 1, wherein the first period and the second period correspond to a same frame period.

12. The display device of claim 1, wherein the light emitting pixel is configured to not emit light in the second period.

13. The display device of claim 1, wherein the sensing region is a fingerprint sensing region configured to sense a fingerprint of a user.

14. The display device of claim 1, wherein the panel driver includes:
a data driver configured to provide a data voltage to the light emitting pixel through a data line;
a scan driver configured to provide a write signal to the light emitting pixel and the light sensing pixel, and to further provide a compensation signal, an initialization signal and a bypass signal to the light emitting pixel;
an emission driver configured to provide an emission signal to the light emitting pixel; and
a readout circuit connected to the light sensing pixel through a readout line, and configured to provide a global reset signal to the light sensing pixel.

15. The display device of claim 14, wherein the light emitting pixel includes:
a first transistor configured to generate a driving current;
a second transistor configured to transfer the data voltage in response to the write signal;
a third transistor configured to diode-connect the first transistor in response to the compensation signal;
a fourth transistor configured to transfer an initialization voltage to a gate of the first transistor in response to the initialization signal;
a fifth transistor configured to connect a line that is configured to transfer a first power supply voltage and the first transistor in response to the emission signal;
a sixth transistor configured to connect the first transistor and the light emitting element in response to the emission signal;
a seventh transistor configured to transfer an anode initialization voltage to the light emitting element in response to the bypass signal;
a storage capacitor connected between the line that is configured to transfer the first power supply voltage and the gate of the first transistor; and
the light emitting element configured to emit light based on the driving current.

16. The display device of claim 15, wherein the light sensing pixel includes:
an eighth transistor configured to generate the sensing current based on a voltage of an internal node connected to the organic photodiode;
a ninth transistor configured to transfer a reset voltage to the internal node in response to the global reset signal;
a tenth transistor configured to connect the eighth transistor and the readout line in response to the write signal; and
the organic photodiode.

17. The display device of claim 16, wherein the global reset signal has an on-level in the first period and the second period.

18. A method of operating a display device including a light emitting pixel and a light sensing pixel within a sensing region, the method comprising:
driving the light emitting pixel to emit light with a first luminance in a first period;
resetting an organic photodiode of the light sensing pixel in a second period;
driving the light emitting pixel to emit light with a second luminance such that the organic photodiode receives reflected light in a third period; and
receiving a sensing current corresponding to an intensity of the reflected light from the light sensing pixel in a fourth period,
wherein the first luminance in the first period is higher than the second luminance in the third period.

19. The method of claim 18, wherein the second luminance is lower than a maximum luminance of the light emitting pixel in a normal mode, and
wherein the first luminance is higher than the maximum luminance of the light emitting pixel in the normal mode.

20. The method of claim 18, wherein a first data voltage provided to the light emitting pixel to emit light with the first luminance is lower than a second data voltage provided to the light emitting pixel to emit light with the second luminance.

21. An electronic device comprising:
a processor configured to provide image data; and
a display device configured to display an image based on the image data, the display device including:
a display panel including a light emitting pixel having a light emitting element and a light sensing pixel having an organic photodiode within a sensing region; and
a panel driver configured to drive the display panel,
wherein the panel driver is further configured to:
drive the light emitting pixel to emit light with a first luminance in a first period;
reset the organic photodiode of the light sensing pixel in a second period;
drive the light emitting pixel to emit light with a second luminance such that the organic photodiode receives reflected light in a third period; and
receive a sensing current corresponding to an intensity of the reflected light from the light sensing pixel in a fourth period, and
wherein the first luminance in the first period is higher than the second luminance in the third period.
